(19) United States
(12) Patent Application Publication
(10) Pub. No.: US 2026/0033290 A1
(43) Pub. Date: Jan. 29, 2026

(54) SUBSTRATE LIFTING DEVICE, AND SUBSTRATE LOADING AND UNLOADING METHOD USING THE SAME

(71) Applicant: Samsung Electronics Co., Ltd., Suwon-si (KR)

(72) Inventors: JONGSUK YOON, Suwon-si (KR); MUYER LEE, Suwon-si (KR); CHANO CHOI, Suwon-si (KR); HYUNGN CHOI, Suwon-si (KR)

(21) Appl. No.: 19/013,247

(22) Filed: Jan. 8, 2025

(30) Foreign Application Priority Data
Jul. 29, 2024 (KR) 10-2024-0100247

(51) Int. Cl. H01L 21/687; H01L 21/67

(52) U.S. Cl. CPC H01L 21/68742; H01L 21/67259; H01L 21/68764

(57) ABSTRACT

Disclosed is a substrate lifting device according to an embodiment which includes: a lift pin having one side supporting a substrate, and including a hollow line therein; a plate fixing the other side of the lift pin; a driving unit configured to move the chuck or the plate so that the lift pin moves along the pinhole; and sensors connected to the hollow line, and configured to transmit and receive signals through the hollow line.

### CROSS-REFERENCE TO RELATED APPLICATION

This application claims priority under 35 U.S.C. § 119 to and the benefit of Korean Patent Application No. 10-2024-0100247, filed in the Korean Intellectual Property Office on Jul. 29, 2024, the entire contents of which are incorporated herein by reference.

### BACKGROUND OF THE INVENTION

### (a) Field of the Invention

The present disclosure relates to a substrate lifting device, and a substrate loading and unloading method using the same.

### (b) Description of the Related Art

A chuck fixing a wafer is provided in a process chamber in which a semiconductor manufacturing process is performed. The chuck includes three or more lift pins used for loading the wafer, and a driving device lifting up and down the lift pin or the chuck therein.

According to lift-up and down of the lift pin or chuck by the driving device, the lift pin protrudes or is recessed from the chuck by penetrating a pinhole provided in the chuck. The lift pin supports the wafer in a state in which an upper end of the lift pin protrudes from the chuck. Thereafter, the lift pin seats and loads the wafer on an upper surface of the chuck while being recessed into the pinhole.

After a specific process is completed, the wafer seated on the chuck is unloaded, and transferred to a chamber in which a next process is performed. In such an unloading process, the lift pin protrudes from the chuck in a state of supporting the wafer, and a robot arm that transfers the wafer unloads the wafer from the lift pin while the lift pin protrudes.

However, in a lifting device in related art, there is a case where an abnormal operation occurs in a movement process of the lift pin such as a case where a height of any one of a plurality of lift pins is different, and in this case, there is a problem in that the wafer is not loaded in a horizontal state.

Further, even though the wafer is disposed in the lift pin, this cannot be detected, and the wafer is redundantly loaded, so there may be a collision between the wafers.

### SUMMARY OF THE INVENTION

Embodiments of the present disclosure provide a substrate lifting device, and a substrate loading and unloading method using the same, in which a sensor disposed in a lift pin transmits and receives a signal through a hollow line formed inside the lift pin to detect whether a substrate is disposed at one side of the lift pin, thereby preventing a problem which occurs in a process of loading and unloading, such as redundantly loading the substrate in a loading process.

Further, embodiments of the present disclosure provide a substrate lifting device, and a substrate loading and unloading method using the same, in which the sensor detects whether a plurality of lift pins protrude from the chuck at the same height to minimize a substrate damage risk.

An embodiment provides a substrate lifting device which may include: a lift pin having one side supporting a substrate, and including a hollow line therein; a chuck including a pinhole penetrated by the lift pin, and having one side on which the substrate is seated, a plate fixing the other side of the lift pin; a driving unit configured to move the chuck or the plate so that the lift pin moves along the pinhole; and sensors connected to the hollow line, and transmitting and receiving signals through the hollow line.

Another embodiment provides a substrate lifting device which may include: a lift pin having one side supporting a substrate, and including a hollow line therein; a chuck including a pinhole penetrated by the lift pin, and having one side on which the substrate is seated; a plate fixing the other side of the lift pin; a driving unit configured to move the chuck or the plate so that the lift pin moves along the pinhole; sensors connected to the hollow line, and configured to transmit and receive signals through the hollow line; a determination unit configured to analyze the signals to determine whether the substrate is disposed at the one side of the lift pin, and determine whether the lift pin performs an abnormal operation in the process of loading and unloading the substrate; and a control unit configured to control the driving unit to stop or terminate the process of loading and unloading the substrate according to the determination of the determination unit.

Yet another embodiment provides a method for loading and unloading a substrate by using a substrate lifting device, the substrate lifting device including a plurality of lift pins, a chuck including a plurality of pinholes penetrated by the plurality of lift pins, a plate fixing one side of each of the plurality of lift pins, a driving unit moving the chuck or the plate, and a plurality of sensors disposed close to the one side of each of the plurality of lift pins, the plurality of sensors including first sensors and second sensors, the method may include: detecting, by each of the first sensors, whether the substrate is disposed at the one side of each of the plurality of lift pins in a state in which one side of the chuck is disposed at a first location higher than the one side of the plurality of lift pins; detecting, by each of the second sensors, whether a specific portion of a lateral surface of each of the plurality of lift pins is surrounded by a corresponding one of the plurality of pinholes; moving, by the driving unit, the chuck or the plate so that the chuck is positioned at a second location where the other side of the chuck is disposed close to the other side of the plurality of lift pins when the first sensors do not detect the substrate and the second sensors detect the plurality of pinholes; disposing, by a substrate transfer unit, the substrate at the one side of the plurality of lift pins; and seating, by the driving unit, the substrate on the one side of the chuck, and loading the substrate by moving the chuck or the plate so that the chuck is positioned at the first location.

According to embodiments, in the loading and unloading process of the substrate, a state in which the chuck and the lift pin are disposed, and a state in which the substrate is disposed are detected to minimize substrate damage which occurs in the loading and unloading process of the substrate.

### BRIEF DESCRIPTION OF THE DRAWINGS

FIG. 1 is a diagram illustrating a substrate lifting device in related art.

FIGS. 2A-2B are diagrams for describing a lifting device in the related art according to FIG. 1.

FIGS. 3A-3B are diagrams illustrating an operation process of the lifting device in the related art according to FIG. 1.

FIG. 4 is a diagram illustrating a substrate lifting device according to an example embodiment.

FIG. 5 is a diagram illustrating a substrate lifting device according to an example embodiment.

FIG. 6 is a diagram illustrating a configuration of the substrate lifting device according to an example embodiment.

FIGS. 7A-7E are diagrams illustrating a substrate loading method according to an example embodiment.

FIG. 8 is a diagram describing a substrate loading method according to an example embodiment.

FIGS. 9A-9B are diagrams illustrating a process after substrate loading in the substrate loading method according to FIG. 8.

FIGS. 10A-10B are diagrams illustrating a process after the substrate loading in the substrate loading method according to FIG. 8.

FIGS. 11A-11E are diagrams illustrating a substrate unloading method according to an example embodiment.

FIG. 12 is a diagram describing a substrate unloading method according to an example embodiment.

FIGS. 13A-13B are diagrams illustrating a process before substrate unloading in the substrate unloading method according to FIG. 12.

### DETAILED DESCRIPTION OF THE EMBODIMENTS

Hereinafter, embodiments of the present disclosure will be described more fully hereinafter with reference to the accompanying drawings so as to be implemented by those skilled in the art to which the present disclosure pertains. The present disclosure may be implemented in various different forms and is not limited to embodiments described herein.

Parts not associated with required description are omitted for clearly describing the present invention and like reference numerals designate like elements throughout the specification.

In addition, each configuration illustrated in the drawings is arbitrarily shown for understanding and ease of description, but the present disclosure is not limited thereto. In the drawings, the thickness of layers, films, panels, regions, etc., are exaggerated for clarity. In addition, in the drawings, for convenience of description, thicknesses of a part and an area are exaggeratedly illustrated.

Throughout the specification, when it is described that a part is “connected” with another part, it means that the certain part may be “directly connected” with another part and the elements “indirectly connected” to each other with a third member interposed therebetween as well. In addition, unless explicitly described to the contrary, the word “comprise”, and variations such as “comprises” or “comprising”, will be understood to imply the inclusion of stated elements but not the exclusion of any other elements.

Further, it will be understood that when an element such as a layer, film, region, or substrate is referred to as being “on” another element, it can be directly on the other element or intervening elements may also be present. In contrast, when an element is referred to as being “directly on” another element, there are no intervening elements present. In addition, to be referred to as “above” or “on” a reference portion is located above or below the reference portion, and does not particularly mean to “above” or “on” the direction opposite to gravity.

Further, throughout the specification, “plan view” means that a target part is viewed from the top, and “cross-sectional view” means that a cross section vertically cutting the target part is viewed from the side.

A substrate in the present disclosure may mean the substrate itself, or a laminate structure including a predetermined layer or film formed on a surface of the substrate.

Further, the substrate may be a wafer, or may include the wafer and at least one material film on the wafer. However, the substrate is not limited thereto, and may include all of various sizes of plate forms including an LED panel, a glass plate, a thin iron plate, etc.

A substrate lifting device 10 according to the present disclosure includes all devices which lift, and load and unload the wide-range substrate.

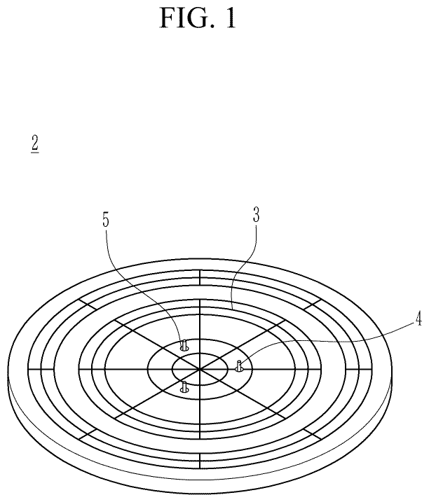

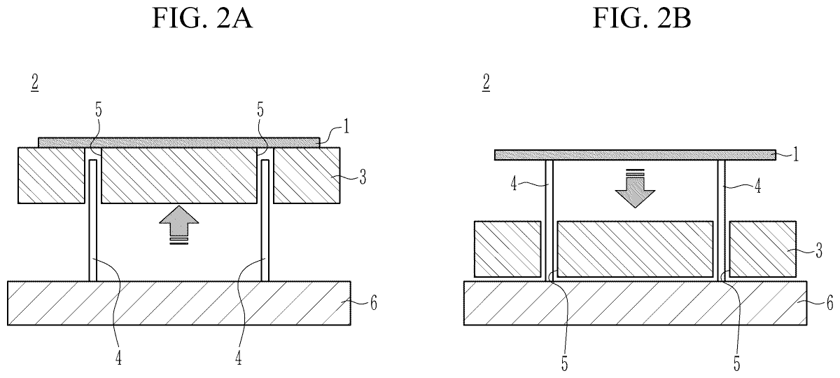

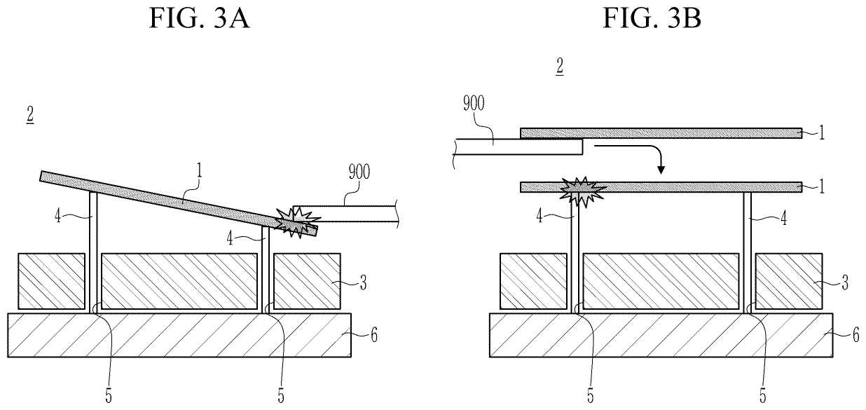

FIG. 1 is a diagram illustrating a substrate lifting device in related art, FIGS. 2A-2B are diagrams for describing a lifting device in the related art according to FIG. 1, and FIGS. 3A-3B are diagrams illustrating an operation process of the lifting device in the related art according to FIG. 1.

FIG. 1 illustrates a lifting device 2 in the related art with three lift pins 4.

FIGS. 2A-2B and 3A-3B simplify and illustrate a side cross-section of the lifting device 2 of FIG. 1. A structure of a chuck 3 penetrated by lift pins 4 is described, and in order to describe a process in which the lift pins 4 move in the lifting device 2, a cross section is illustrated so that two lift pins 4 are shown.

First, referring to FIGS. 2A and 2B, the substrate lifting device 2 in the related art includes the chuck 3 on which a substrate 1 is seated, and pinholes 5, each of which is penetrated by a lift pin 4, is provided in the chuck 3. The lift pins 4 are structures fixed to a plate 6, and the lift pins 4 move up and down by penetrating the pinholes 5. In FIGS. 2A and 2B, it is illustrated that the chuck 3 moves up and down. In this process, the lift pins 4 are disposed so that an upper end of each lift pin 4 is recessed into a respective pinhole 5 (FIG. 2A), and disposed so that the upper end of each lift pin 4 protrudes from the respective pinhole 5 (FIG. 2B).

FIG. 2A illustrates a state in which the substrate 1 is seated on the chuck 3, and the substrate 1 is loaded. As illustrated in FIG. 2A, the chuck 3 moves up, and in a state in which the lift pins 4 are recessed in the pinholes 5 of the chuck 3, the substrate 1 is loaded on the chuck 3.

FIG. 2B illustrates a state in which the chuck 3 moves down in order to upload the substrate 1. As illustrated in FIG. 2B, when the lift pins 4 protrude from the pinholes 5, the chuck 3 and the substrate 1 are spaced apart from each other by a predetermined gap. As such, in a state in which the substrate 1 is spaced apart from the chuck 3, the substrate 1 is unloaded from the lift pins 4, and moved to another place by a robot that transfers the substrate 1.

However, in the case of the lifting device 2 in the related art, there is a problem when an abnormal operation occurs in the lifting device 2 in a process of loading and unloading the substrate 1, such as a case where any one of a plurality of lift pins 4 is disposed to have a different height, etc.

FIGS. 3A-3B are diagrams illustrated to describe a problem which occurs in an operation process of the lifting device in the related art according to FIG. 1.

The lifting device 2 in the related art may not detect whether the lift pins 4 penetrating the pinholes 5 protrude from the chuck 3, and whether all of the plurality of lift pins 4 protrude by an appropriate height, i.e., by a predetermined height of the plurality of lift pins 4.

For example, as illustrated in FIG. 3A, in a step in which the chuck 3 moves down, and the lift pins 4 should protrude from the pinholes 5, there is a case where the plurality of lift pins 4 are disposed to have different heights, such as a case where any one lift pin 4 is bent or crushed, but the lifting device 2 in the related art may not detect this in advance.

In the state of FIG. 3A, when a task of loading the substrate 1 is proceeded on schedule, the substrate 1 is not horizontally disposed one the lift pins 4, so there is a problem in that the substrate 1 is damaged.

Alternatively, as illustrated in FIG. 3A, in order to unload the substrate 1 disposed on the lift pins 4 when substrate 1 is in an inclined state, there is also a problem in that the substrate 1 and a substrate transfer unit 900 are damaged due to a collision between the substrate transfer unit 900 and the substrate 1 during a process in which the substrate transfer unit 900 moves close to the substrate 1.

Next, as illustrated in FIG. 3B, even though the substrate 1 is already disposed on the lift pins 4, this is not detected, and a phenomenon in which the substrate transfer unit 900 redundantly loads the substrate 1 may occur. In this process, the collision between the substrates 1 occurs.

Further, although not illustrated in the drawing, when the process of unloading the substrate 1 is performed in a state in which the substrate 1 is not disposed at one side of the lift pins 4, it is not detected that the substrate 1 is not present, and various errors may occur as a process such as gripping the substrate 1 by the substrate transfer unit 900 is proceeded.

As described above, the lifting device 2 in the related art may check, in advance, whether the substrate 1 is disposed in the process of loading and unloading the substrate 1 on and from the chuck 3, and whether the substrate 1 is horizontally disposed if the substrate 1 is disposed, so the lifting device 2 in the related art becomes a problem.

In a process of loading and unloading the substrate 1 on and from the lifting device 2, it is checked whether the lift pins 4 normally move according to each process, and whether the substrate 1 is already loaded, a problem such as the damage of the substrate 1 needs to be solved.

A lifting device 10, and a substrate loading and unloading method using the same according to the present disclosure have a purpose of solving the problem by checking whether each component normally moves according to each process, and whether the substrate 1 is disposed at an appropriate location in advance in the process of loading and unloading the substrate 1 on and from the substrate lifting device 10.

Hereinafter, the substrate lifting device 10, and the substrate loading and unloading method using the same according to an embodiment of the present disclosure will be described in more detail with reference to drawings.

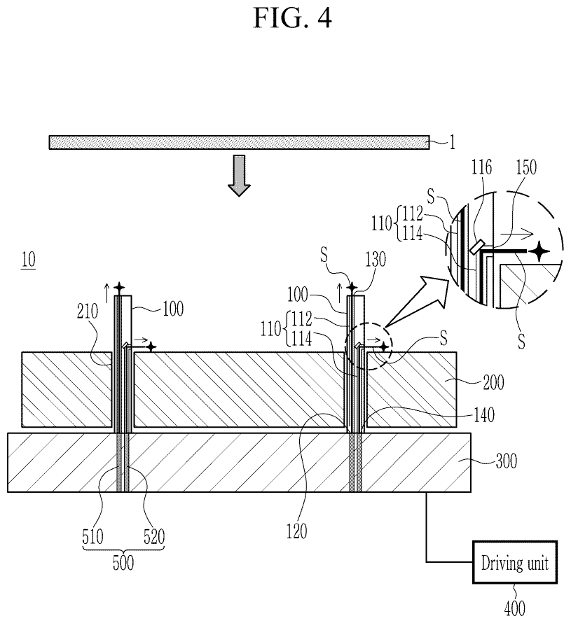

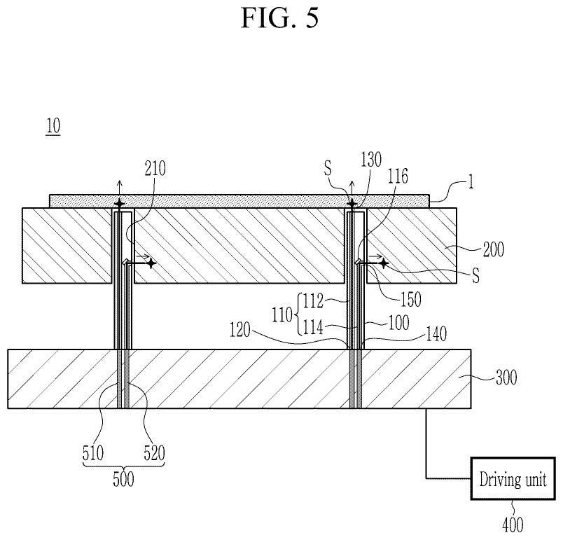

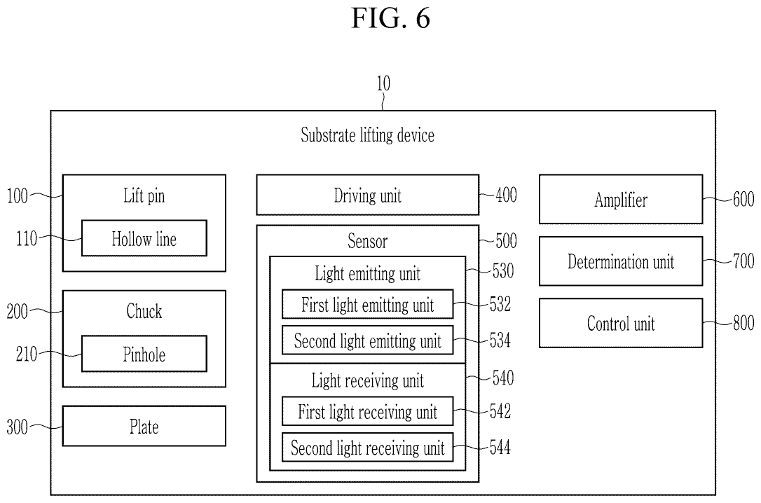

FIGS. 4 and 5 are diagrams illustrated to describe a substrate lifting device according to an example embodiment, and FIG. 6 is a diagram illustrating a configuration of the substrate lifting device according to an example embodiment.

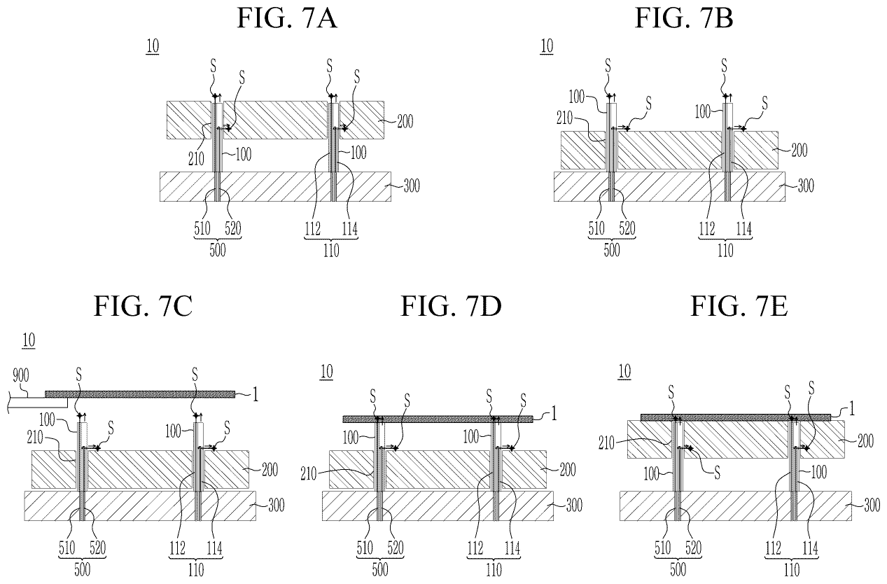

First, a process of loading the substrate 1 by using the substrate lifting device 10 according to the present disclosure will be described with reference to FIGS. 7A-7E to be described below. In a state illustrated in FIG. 7A, a substrate loading process starts while it is sensed that the substrate 1 is not seated on one side (e.g., an upper surface) of a chuck 200.

As illustrated in FIG. 7B, when the chuck 200 is lifted down and the lift pins 100 protrude from the upper surface of the chuck 200, a substrate transfer unit 900 transfers the substrate 1 as illustrated in FIG. 7C. As illustrated in FIG. 7D, after the transferred substrate 1 is disposed at one side of the lift pins 100, the chuck 200 is lifted up, so the substrate 1 is seated on one side, i.e., the upper surface of the chuck 200 to terminate the substrate loading process as illustrated in FIG. 7E.

FIG. 4 illustrates a state in which lift pins 100 protrude from the upper surface of the chuck 200 in a state in which the chuck 200 is lifted down as illustrated in FIG. 7B, and FIG. 5 is a diagram illustrating a state in which the chuck 200 is lifted up, and the lift pins 100 are recessed in the chuck 200 unlike FIG. 4.

However, in FIG. 4, the substrate 1 is additionally illustrated unlike FIG. 7B, in order to describe a direction and a location in which the substrate 1 is loaded on the substrate lifting device 10. Specifically, in FIG. 4, a state in which the substrate 1 moves toward one side of the lift pins 100 of the substrate lifting device 10 is additionally illustrated.

However, FIG. 4 does not mean the state in which the substrate 1 is disposed at one side of the lift pins 100, so it is assumed and described that a first sensor 510 detecting whether the substrate 1 is disposed at one side of the lift pins 100 may not detect the substrate 1.

FIG. 5 illustrates a state in which the substrate 1 is loaded on the substrate lifting device 10.

As illustrated in FIGS. 4 and 5, the substrate lifting device 10 according to the present disclosure may include a lift pin 100 having one side supporting the substrate 1, and including a hollow line 110 therein, a chuck 200 including a pinhole 210 penetrated by the lift pin 100, and having one side on which the substrate 1 is seated, a plate 300 fixing the other side of the lift pin 100, a driving unit 400 moving the chuck 200 or a plate 300 so that the lift pin 100 moves up and down along the pinhole 210, and a sensor 500 disposed close to the other side of the lift pin 100 to transmit and receive a signal S through a hollow line 110.

As illustrated in FIGS. 4 and 5, the sensor 500 is disposed to be connected to the other side of the lift pins 100, and in FIGS. 4 and 5, it is illustrated that the sensor 500 is disposed inside the plate 300. However, the disposition of the sensor 500 is not limited to the illustrated disposition.

According to the embodiment, as illustrated in FIG. 6, the substrate lifting device 10 according to the present disclosure may include a determination unit 700 which analyzes the signal S to determine whether the substrate 1 is disposed at one side of the lift pins 100, and determine whether the lift pins 100 perform an abnormal operation in the loading and unloading process of the substrate 1. Although not illustrated, in example embodiments, the determination unit 700 and the control unit 800 can include one or more of the following components: at least one central processing unit (CPU) configured to execute computer program instructions to perform various processes and methods, random access memory (RAM) and read only memory (ROM) configured to access and store data and information and computer program instructions, input/output (I/O) devices configured to provide input and/or output to the determination unit 700 and/or the control unit 800, and storage media or other suitable type of memory (e.g., such as, for example, RAM, ROM, programmable read-only memory (PROM), erasable programmable read-only memory (EPROM), electrically erasable programmable read-only memory (EEPROM), magnetic disks, optical disks, floppy disks, hard disks, removable cartridges, flash drives, any type of tangible and non-transitory storage medium) where data and/or instructions can be stored. In addition, the determination unit 700 and the control unit 800 can include antennas, network interfaces that provide wireless and/or wire line digital and/or analog interface to one or more networks over one or more network connections (not shown), a power source that provides an appropriate alternating current (AC) or direct current (DC) to power one or more components of the determination unit 700 and the control unit 800, and a bus that allows communication among the various components of the determination unit 700 and the control unit 800.

Further, the substrate lifting device 1 may include a control unit 800 that controls the driving unit 400 to stop or terminate the loading and unloading process of the substrate 1 according to the determination of the determination unit 700.

In the case of a structure in which the signals S transmitted and received by the sensor 500 head to one side (e.g., upper side) and a lateral surface of the lift pin 100, respectively through the hollow line 110, a form and a disposed location of the sensor 500 may be diversified.

The sensor 500 may include a first sensor 510 and a second sensor 520, and this will be described below.

First, the driving unit 400 serves to move the chuck 200 or the plate 300.

FIG. 4 illustrates a state in which the chuck 200 is disposed at a second location, and an upper end of each of the lift pins 100 protrudes from the corresponding pinhole 210. For example, upper ends of the lift pins 100 may be higher than an upper surface of the chuck 200.

FIG. 5 illustrates a state in which the chuck 200 is disposed at a first location, and illustrates a state in which the upper end of each of the lift pins 100 is recessed into the pinhole 210. For example, upper ends of the lift pins 100 may be higher than a lower surface of the chuck 200 and lower than an upper surface of the chuck 200.

That is, the driving unit 400 may move the chuck 200 or the plate 300 so that the chuck 200 is positioned between a first location where one side of the chuck 200 is disposed to be higher than one side of the lift pins 100, and a second location where the other side of the chuck 200 is disposed close to the other side of the lift pins 100.

In FIGS. 4 and 5, an embodiment in which the driving unit 400 is connected to the plate 300, illustrate a case where the plate 300 moves up and down and the chuck 200 does not move.

Although not illustrated, there may be a structure in which the driving unit 400 is connected to the chuck 200, and as a result, the chuck 200 may also be moved up and down.

The hollow line 110 is included inside the lift pin 100.

The hollow line 110 may include a first hollow line 112 connecting a first opening 120 provided at one side of the lift pin 100, and a second opening 130 provided at the other side, and a second hollow line 114 connecting a third opening 140 provided at one side of the lift pin 100, and a fourth opening 150 on a lateral surface of the lift pin 100.

As illustrated, the first hollow line 112 has a straight-line form, and the second hollow line 114 has a shorter straight-line form than the first hollow line 112, and has an ‘L’ form which is horizontally extended to be extended therefrom.

The first hollow line 112 and the second hollow line 114 may be connected to the first sensor 510 and the second sensor 520, respectively. Each hollow line 110 serves as a passage that moves the signal S transmitted by the sensor 500 connected thereto along each hollow line 110. When the transmitted signal S is reflected on and returned from a specific target, the hollow line 110 may also serve as a passage through which the reflected signal S moves.

A reflector 116 reflecting the signal S may be disposed inside the second hollow line 114. The reflector 116 serves to change a path of the signal S so that the signal S may move along a direction of the second hollow line 114 inside the second hollow line 114 having the ‘L’ form.

The fourth opening 150 disposed on the lateral surface of the lift pin 100 is surrounded by the pinhole 210 in the state in which the chuck 200 is disposed at the first location (see FIG. 4).

Further, the fourth opening 150 may be disposed at a location deviating from the pinhole 210 in the state in which the chuck 200 is disposed at the second location (see FIG. 5).

The sensor 500 according to the present disclosure serves to detect whether the substrate 1 is disposed at one side of the lift pin 100 and whether a specific portion on the lateral surface of the lift pin 100 is surrounded by the pinhole 210. For example, the sensor 500 may detect whether the substrate 1 contacts the one side of the lift pin 100.

The first sensor 510 detects the signal S transmitted through the first hollow line 112 to detect whether the substrate 1 is disposed at one side of the lift pin 100, i.e., the second opening 130.

The second sensor 520 detects the signal S transmitted through the second hollow line 114 to detect whether the fourth opening 150 is disposed inside the pinhole 210. That is, the second sensor 520 detects whether a specific portion on the lateral surface of the lift pin 100 at which the fourth opening 150 is disposed is surrounded by the pinhole 210.

As illustrated in FIG. 6, the sensor 500 may include a light emitting unit 530 and a light receiving unit 540.

The first sensor 510 may include a first light emitting unit 532 transmitting the signal S toward the second opening 130 from the first opening 120 through the first hollow line 112, and a first light receiving unit 542 receiving the signal S reflected and returned on the second opening 130.

The second sensor 520 may include a second light emitting unit 534 transmitting the signal S toward the fourth opening 150 from the third opening 140 through the second hollow line 114, and a second light receiving unit 544 receiving the signal S reflected and returned on the fourth opening 150.

According to the embodiment, the signal S transmitted and received by the sensor 500 may be an optical signal S.

An electrical signal S transmitted from the outside to the sensor 500 may be converted into the optical signal S by the sensor 500. In contrast, the sensor 500 may convert the optical signal S into the electrical signal S again, and transmit the converted electrical signal S to the outside.

In this case, the light emitting unit 530 may serve to convert the electrical signal S transmitted from the outside into the optical signal S, and transmit the optical signal S toward the second opening 130 and the fourth opening 150.

The light receiving unit 540 may serve to receive the optical signal reflected and returned on the second opening 130 and the fourth opening 150, and convert the received optical signal S into the electrical signal S.

The light emitting unit 530 may be a light emitting element, and the light receiving unit 540 may be a light receiving element.

Specifically, the first light emitting unit 532 of the first sensor 510 serves to convert the electrical signal S transmitted to the first opening 120 into the optical signal S, and transmit the optical signal S toward the second opening 130 from the first opening 120. Further, the first light receiving unit 542 of the first sensor 510 serves to receive the optical signal S reflected and returned toward the first opening 120 from the second opening 130, and convert the received optical signal S into the electrical signal S.

The second light emitting unit 534 of the second sensor 520 serves to convert the electrical signal S transmitted to the third opening 140 into the optical signal S, and transmit the optical signal S toward the fourth opening 150 from the third opening 140. Further, the second light receiving unit 544 of the second sensor 520 serves to receive the optical signal S reflected and returned toward the third opening 140 from the fourth opening 150, and convert the received optical signal S into the electrical signal S.

Further, the substrate lifting device 10 may further include an amplifier 600 that amplifies the electrical signal S converted by the light receiving unit 540, and further include a determination unit 700 that analyzes the electrical signal S converted by the light receiving unit 540.

The determination unit 700 analyzes the signal S detected by the sensor 500 to determine whether the substrate 1 is disposed at one side of the lift pin 100, and determine whether the lift pin 100 performs the abnormal operation in the loading and unloading process of the substrate 1.

Specifically, the determination unit 700 analyzes the electrical signal S received and converted by the first light receiving unit 542 of the first sensor 510 to determine whether the substrate 1 is disposed at one side of the lift pin 100. The reason is that the first sensor 510 determines whether a target (substrate 1) is disposed at a location close to the second opening 130 provided at one side of the lift pin 100.

In the case of FIG. 4, as a state in which the substrate 1 is not disposed at one side of the lift pins 100, an undetected result is obtained by all of the first sensors 510. In FIG. 4, an “undetected result” may be a result indicating that the substrate 1 is not detected at one side of the lift pins 100.

As described above, the substrate 1 illustrated in FIG. 4 is used for describing a direction in which the substrate 1 is disposed, and the substrate 1 is not disposed at one side of the lift pin 100.

In the case of FIG. 5, as the state in which the substrate 1 is disposed at one side (upper surface) of the chuck 200, a detected result is obtained by all of the first sensors 510.

The determination unit 700 analyzes the electrical signal S received and converted by the second light receiving unit 544 of the second sensor 520 to determine whether the lift pin 100 performs the abnormal operation in the process of loading and unloading the substrate 1 on and from the chuck 200. The reason is that the second sensor 520 determines whether the target (pinhole 210) is disposed at a location close to the fourth opening 150 disposed on the lateral surface of the lift pin 100, i.e., the specific portion of the lateral surface.

The second sensor 520 detecting the target means that the fourth opening 150 is disposed inside the pinhole 210, and surrounded by the pinhole 210.

That is, in the case of FIG. 4, the undetected result is obtained by all of the second sensors 520 and in the case of FIG. 5, the detected result is obtained by all of the second sensors 520.

In FIGS. 4 and 5, an embodiment in which one first sensor 510 and one second sensor 520 are included in each lift pin 100 is illustrated.

However, the number of sensors 500 provided in the lift pin 100 is not particularly limited to two. Two or more sensors 500 may be disposed.

As appropriate, one sensor 500 is further disposed to further detect whether another portion (another portion other than the fourth opening 150) on the lateral surface of the lift pin 100 is surrounded by the pinhole 210.

For example, when it is intended to further detect whether another portion (another portion other than the fourth opening 150) on the lateral surface of the lift pin 100 is surrounded by the pinhole 210, an opening (not illustrated) may be further included in a location other than the fourth opening 150.

Further, in FIGS. 4 and 5, an embodiment in which each of the signal S transmitted and the signal S received by each sensor 500 moves through one hollow line 110 is illustrated.

According to another embodiment, the signal S transmitted and the signal S received by each sensor 500 may also move through different hollow lines 110. In this case, unlike illustrated in FIGS. 4 and 5, the numbers of hollow lines 110 and openings will be further increased.

That is, the number of sensors 500 and the number of hollow lines 110 in the present disclosure are not limited to the illustrated numbers, but various combinations may be possible according to the embodiment.

FIGS. 7A-7E are diagrams illustrating a substrate loading method according to an example embodiment. First, referring to FIG. 7A, as a state in which the chuck 200 is lifted up (a state in which the chuck 200 is disposed at a first location), the upper end of each of the lift pins 100 is recessed inside the corresponding pinhole 210 of the chuck 200. In this state, it is detected that the substrate 1 is not seated on one side of the chuck 200, and when the substrate 1 is not detected, the substrate loading process is started. That is, in the state of FIG. 7A, when the substrate is not disposed at one side of the lift pins 100 and the chuck 200, the substrate loading process is not started.

Therefore, in the state of FIG. 7A, in the state in which the chuck 200 is placed at the first location, each first sensor 510 detects whether the substrate 1 is disposed at one side of each lift pin 100.

When a plurality of first sensors 510 do not detect the substrate 1, the driving unit 400 moves the chuck 200 so that the chuck 200 is positioned at a second location at which the other side of the chuck 200 is disposed close to the other side of a plurality of lift pins 100 (FIG. 7B).

That is, in FIG. 7A, when each first sensor 510 does not detect the substrate 1, that is, it is confirmed that the substrate 1 is not disposed, the chuck 200 is lifted down as in FIG. 7B.

Additionally, in FIG. 7A, each second sensor 520 may detect the pinhole 210. When all second sensors 520 detect the pinholes 210, it may be regarded that the lift pins 100 are normally operated.

FIG. 7B which illustrates a state in which the chuck 200 is lifted down illustrates a state in which the lift pins 100 protrude from the upper surface of the chuck 200.

In the state of FIG. 7B, it is checked whether the chuck 200 moves to the second location, whether all lift pins 100 protrude from the pinholes 210, and whether all heights of the protruding lift pins 100 are the same as each other (whether there is a bent lift pin 100).

Each second sensor 520 may detect whether a specific portion on the lateral surface of each lift pin 100 is surrounded by the pinhole 210. Here, the specific portion on the lateral surface of the lift pin 100 means a portion where the fourth opening 150 is disposed.

In FIG. 7B, a case where each of all second sensors 520 does not detect the pinhole 210 means that each of all lift pins 100 protrudes from the chuck 200 by an appropriate height. That is, the case means that the lift pins 100 are not bent, but penetrate the pinholes 210.

When it is confirmed that all of the lift pins 100 penetrate the pinholes 210 without an error, the substrate transfer unit 900 transfers the substrate 1 to locate the substrate 1 to be close to one side of the lift pin 100 as in FIG. 7C.

As in FIG. 7C, just before the substrate transfer unit 900 disposes the substrate 1, both the first sensor 510 and the second sensor 520 should not detect the substrate 1.

In the state of FIG. 7C, when at least one first sensor 510 of the plurality of first sensors 510 detects the substrate 1, the substrate loading process may be stopped. The reason is that there is a problem in that the substrate 1 is redundantly loaded.

Further, when at least one second sensor 520 of the plurality of second sensors 520 detects the pinhole 210, the substrate loading process may be stopped. The reason is that the lift pin 100 is not normally operated.

FIG. 7D illustrates a state in which one side of the lift pins 100 supports the substrate 1. Each first sensor 510 detects whether the substrate 1 is disposed at one side of each lift pin 100, and each second sensor 520 checks whether a specific portion on the lateral surface of each lift pin 100 is surrounded by the pinhole 210.

In FIG. 7D, all first sensors 510 should detect the substrate 1, and all second sensors 520 should not detect the pinhole 210. In this case, as in FIG. 7E, the chuck 200 is lifted up, and the substrate 1 is seated on one side, i.e., the upper surface of the chuck 200 to load the substrate 1 to the chuck 200.

However, in FIG. 7D, when at least one second sensor 520 of the plurality of second sensors 520 detects the pinhole 210, the substrate loading process may be stopped. The reason is that even though all first sensors 510 detect the substrate 1, there is a possibility that the disposed substrate 1 will be tilted. That is, the reason is that the lift pin 100 is not normally operated.

As in FIG. 7E, even in a state in which the chuck 200 moves to the first location, and the substrate 1 is seated on the chuck 200, the first sensor 510 and the second sensor 520 detect whether there is an abnormal operation in a loading process.

That is, each first sensor 510 detects whether the substrate 1 is disposed at one side of each lift pin 100, and each second sensor 520 detects whether the lateral surface of each lift pin 100 is surrounded by the pinhole 210.

In this case, when all of the plurality of first sensors 510 and second sensors 520 detect the respective targets, the substrate loading process is terminated.

When an undetected result is obtained even in any one sensor 500, the substrate 1 is wrongly disposed or the operation of any of the lift pins 100 is abnormal. For example, the “undetected result” may be a result indicating that the substrate 1 is wrongly disposed or the operation of any of the lift pins 100 is abnormal. Therefore, the substrate loading process is not terminated, and may be stopped, and then it may be checked whether the substrate loading process is abnormal.

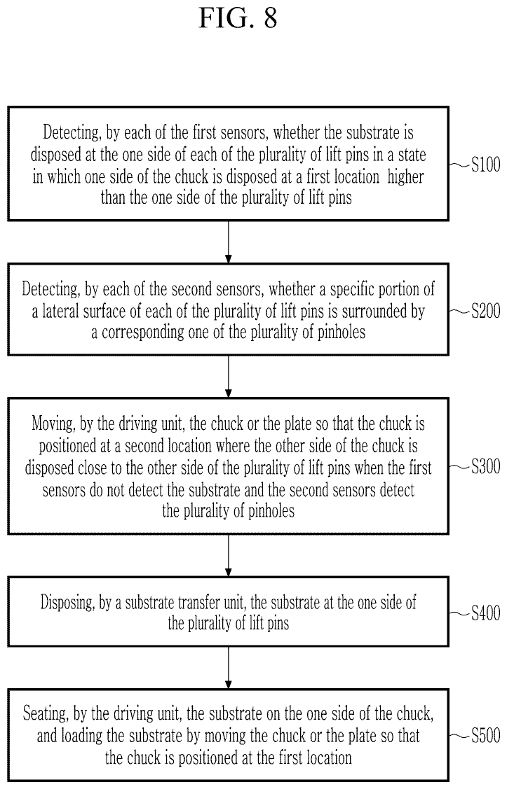

FIG. 8 is a diagram describing a substrate loading method according to an example embodiment.

The substrate loading method according to the present disclosure is a method for loading the substrate 1 by using the substrate lifting device described in FIGS. 4 to 6.

Here, the substrate lifting device 10 may include a plurality of lift pins 100, a chuck 200 including a plurality of pinholes 210 penetrated by respective lift pins 100, a plate 300 fixing the other side of each lift pin 100, and a driving unit 400 moving the chuck 200 or the plate 300. Further, the substrate lifting device 10 may include a plurality of sensors 500 disposed close to the other side of each lift pin 100, and the plurality of sensors 500 may include a first sensor 510 and a second sensor 520.

Referring to FIGS. 7A-7E and 8, the substrate loading method according to the present disclosure may include a step S100 in which each first sensor 510 detects whether the substrate 1 is disposed at one side of each lift pin 100 in the state in which the chuck 200 is placed at the first location, and a step S200 in which each second sensor 520 detects whether a specific portion on the lateral surface of each lift pin 100 is surrounded by the pinhole 210.

Further, the substrate loading method may include a step S300 in which, when the plurality of first sensors 510 do not detect the substrate 1 and the plurality of second sensors 520 detect the pinhole 210, the driving unit 400 moves the chuck 200 or the plate 300 so that the chuck 200 is positioned at a second location at which the other side of the chuck 200 is disposed close to the other side of a plurality of lift pins 100.

Further, the substrate loading method may include a step S400 in which the substrate transfer unit 900 disposes the substrate 1 at one side of the plurality of lift pins 100, and a step S500 in which the driving unit 400 loads the substrate 1 by seating the substrate 1 on one side of the chuck 200 by moving the chuck 200 or the plate 300 so that the chuck 200 is positioned at the first location.

The substrate loading method according to the present disclosure may include a step in which the determination unit 700 determines whether the abnormal operation occurs in the substrate loading process according to the detected and undetected results in the plurality of sensors 500.

Further, the substrate loading method may include a step in which when the determination unit 700 determines that the abnormal operation occurs, the control unit 800 controls the substrate lifting device 10.

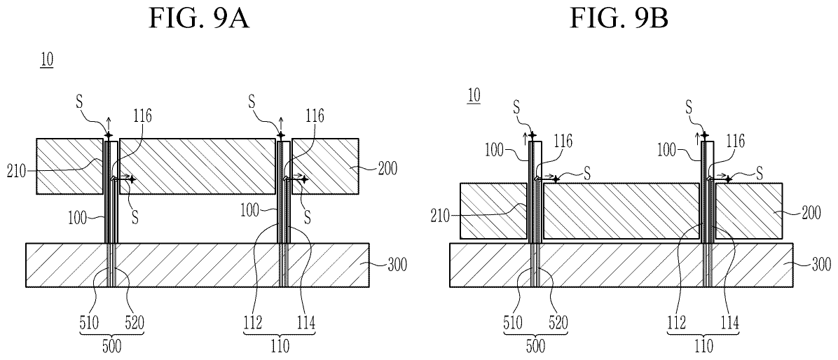

FIGS. 9A-9B are diagrams illustrated to describe a process before substrate loading in the substrate loading method according to FIG. 8.

FIGS. 9A and 9B are diagrams corresponding to FIGS. 7A and 7B.

FIG. 9A is a diagram for describing a step S100 in which each first sensor 510 detects whether the substrate 1 is disposed at one side of each lift pin 100 in the state in which the chuck 200 is placed at the first location, and a step S200 in which each second sensor 520 detects whether a specific portion on the lateral surface of each lift pin 100 is surrounded by the pinhole 210.

FIG. 9B is a diagram for describing a state in which when the plurality of first sensors 510 do not detect the substrate 1, and the second sensor 520 detects the pinhole 210, the driving unit 400 moves the chuck 200 or the plate 300 so that the chuck 200 is positioned at a second location at which the other side of the chuck 200 is disposed close to the other side of a plurality of lift pins 100, in FIG. 9A.

In the state of FIG. 9B, when both the first sensor 510 and the second sensor 520 do not detect the targets, the substrate transfer unit 900 may dispose the substrate 1 at one side of the lift pins 100.

However, the substrate loading method according to the present disclosure may include a step in which when at least one first sensor 510 of the plurality of first sensors 510 detects the substrate 1 in the state in which the chuck 200 is disposed at the second location before the substrate transfer unit 900 disposes the substrate 1 at one side of the plurality of lift pins 100, the control unit 800 stops the loading process of the substrate 1.

Further, the substrate loading method according to the present disclosure may include when at least one second sensor 520 of the plurality of second sensors 520 detects the pinhole 210, the control unit 800 stops the substrate loading process.

The reason is that in the case of a normal operation, a case where both the first sensor 510 and the second sensor 520 should not detect the targets, but any one sensor 500 detects the target means the abnormal operation in the state of FIG. 9B. In this case, the determination unit 700 determines that the abnormal operation occurs in the substrate loading process, so the control unit 800 controls the substrate lifting device 10 to stop the substrate loading process.

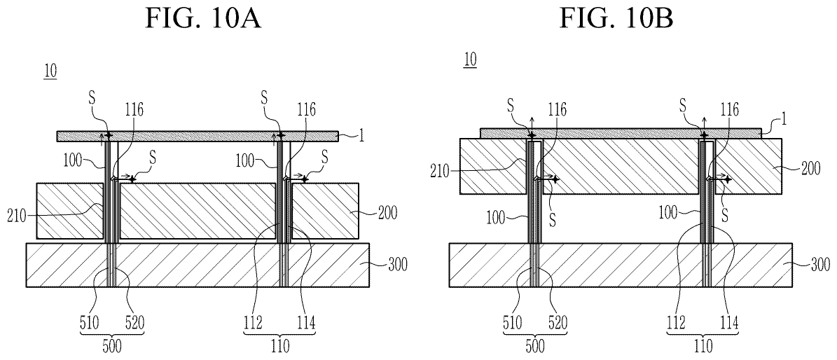

FIGS. 10A-10B are diagrams illustrated to describe a process after the substrate loading in the substrate loading method according to FIG. 8.

FIGS. 10A and 10B are diagrams corresponding to FIGS. 7D and 7E. FIGS. 10A and 10B describe steps until the driving unit 400 moves the chuck 200 or the plate 300 so that the chuck 200 is positioned at the first location after step S400 in which the substrate transfer unit 900 disposes the substrate 1 at one side of the plurality of lift pins 100.

FIG. 10A illustrates a state immediately after disposing the substrate 1 in the lift pin 100, and FIG. 10B illustrates a state in which the chuck 200 moves to the first location in FIG. 10A.

That is, the substrate loading method according to the present disclosure may include a step in which after the substrate transfer unit 900 disposes the substrate 1 at one side of the plurality of lift pins 100, before positioning the chuck 200 at the first location (in the state illustrated in FIG. 10A), each first sensor 510 detects whether the substrate 1 is disposed at one side of the corresponding lift pin 100. Further, the substrate loading method may further include a step in which each second sensor 520 detects whether a specific portion on the lateral surface of the corresponding lift pin 100 is surrounded by the pinhole 210.

In the case of the normal operation illustrated in FIG. 10A, all of the plurality of first sensors 510 detect the substrate 1, and all of the plurality of second sensors 520 do not detect the pinhole 210. In this case, the driving unit 400 may move the chuck 200 or the plate 300 so that the chuck 200 is positioned at the first location.

However, unlike FIG. 10A, when there is the abnormal operation, at least one second sensor 520 of the plurality of second sensors 520 may detect the pinhole 210, and the control unit 800 may stop the substrate loading process.

The case where the second sensor 520 detects the pinhole 210 may mean a case where the lift pin 100 with the second sensor 520 detecting the pinhole 210 does not normally move, or the lift pin 100 is bent or crushed. In this case, when heights of the plurality of lift pins 100 are different, the substrate loading process is stopped.

Even if the substrate 1 is disposed on the lift pin 100, and then the chuck 200 moves to the first location, the abnormal operation may occur in the substrate lifting device 10.

It may once more check whether the substrate lifting device 10 according to the present disclosure normally operates in the state in which the substrate 1 is seated on one side of the chuck 200 after the driving unit 400 moves the chuck 200 or the plate 300 so that the chuck 200 is positioned at the first location as illustrated in FIG. 10B.

Therefore, the substrate lifting method according to the present disclosure further includes a step in which each first sensor 510 detects whether the substrate 1 is disposed at one side of each lift pin 100 in the state of FIG. 10B, and a step in which each second sensor 520 detects whether the lateral surface of each lift pin 100 is surrounded by the pinhole 210. When all of the plurality of first sensors 510 and second sensors 520 detect the respective targets, the control unit 800 may terminate the substrate loading process.

When any one sensor 500 does not detect the target, the control unit 800 may check whether the substrate loading process is abnormal after stopping the substrate loading process without terminating the substrate loading process.

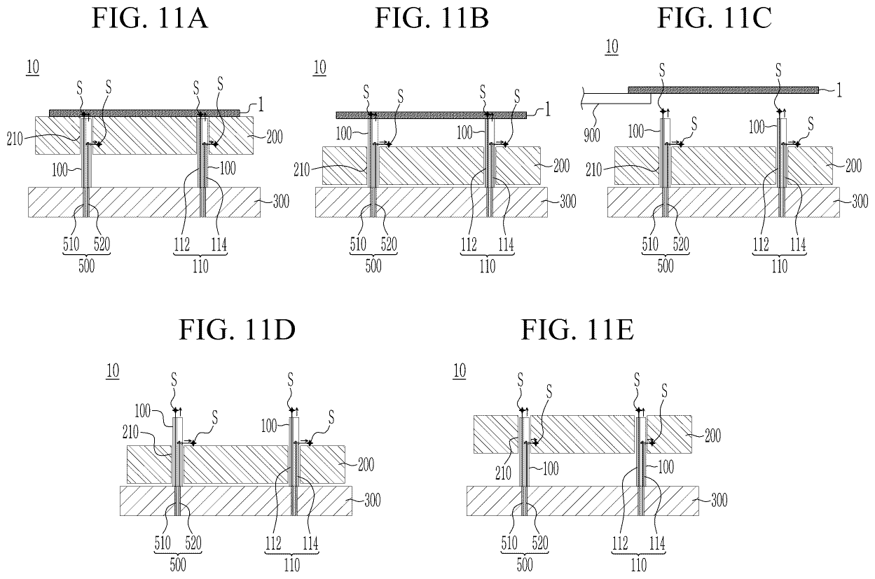

FIGS. 11A-11E are diagrams illustrating a substrate unloading method according to an example embodiment.

First, referring to FIG. 11A, in the state in which the chuck 200 is disposed at the first location, the substrate 1 is seated on the chuck 200. In this state, the substrate 1 should be disposed at one side of all lift pins 100.

In FIG. 11A, each first sensor 510 detects whether the substrate 1 is disposed at one side of each lift pin 100.

Additionally, each second sensor 520 may detect whether a specific portion on the lateral surface of each lift pin 100 is surrounded by the pinhole 210.

When the plurality of first sensors 510 and the second sensors 520 detect the substrate 1 and the pinhole 210, respectively, the driving unit 400 moves the chuck 200 as illustrated in FIG. 11B so that the chuck 200 is positioned at the second location.

That is, in the state of FIG. 11A, all of the first sensors 510 detect the substrate 1, and it is confirmed that the substrate 1 is normally seated on the chuck 200, and then an unloading process of the substrate 1 is started.

FIG. 11B illustrates a state in which the chuck 200 is lifted down to the second location, and in this state, it is checked whether the lift pins 100 protrude from the upper surface of the chuck 200 by an appropriate distance. That is, it is checked whether all lift pins 100 protrude from the pinhole 210, and whether all heights of the protruding lift pins 100 are the same as each other (whether there is the bent lift pin 100).

Each first sensor 510 may detect whether the substrate 1 is disposed at one side of each lift pin 100, and each second sensor 520 may detect whether a specific portion on the lateral surface of each lift pin 100 is surrounded by the pinhole 210.

When all of the plurality of first sensors 510 detect the substrate 1 and all of the plurality of second sensors 520 do not detect the pinhole 210, the substrate transfer unit 900 may unload the substrate 1.

Here, the case where each of all second sensors 520 does not detect the pinhole 210 means that each of all lift pins 100 protrudes from the chuck 200 by an appropriate height. That is, the case means that the lift pin 100 is not bent, but penetrates the pinhole 210.

When all of the lift pins 100 penetrate the pinhole 210 without the error, the substrate 1 disposed at one side of the lift pin 100 is horizontally disposed without an inclination.

As illustrated in FIG. 11B, when it is confirmed that the substrate 1 is horizontally disposed at one side of the protruding lift pin 100, the substrate transfer unit 900 unloads the substrate 1 disposed at one side of the lift pin 100 as illustrated in FIG. 11C.

In FIG. 11B, when at least one first sensor 510 of the plurality of first sensors 510 detects the first substrate 1, or at least one second sensor 520 of the plurality of second sensors 520 detects the pinhole 210, the control unit 800 may stop the substrate loading process.

FIG. 11D is a diagram illustrating a state in which the substrate transfer unit 900 removes the substrate 1 from the lift pins 100. Since the upper end of the lift pins 100 should protrude from the chuck 200 in FIG. 11D, it is checked whether the second sensor 520 detects the pinhole 210 in order to confirm the state.

When all second sensors 520 do not detect the pinhole 210, it may be determined that all second sensors 520 are disposed at the location protruding from the chuck 200.

In FIG. 11D, when it is confirmed that all lift pins 100 protrude while maintaining the appropriate height, the chuck 200 moves to the first location again as in FIG. 11E, and as a result, the substrate unloading process is terminated.

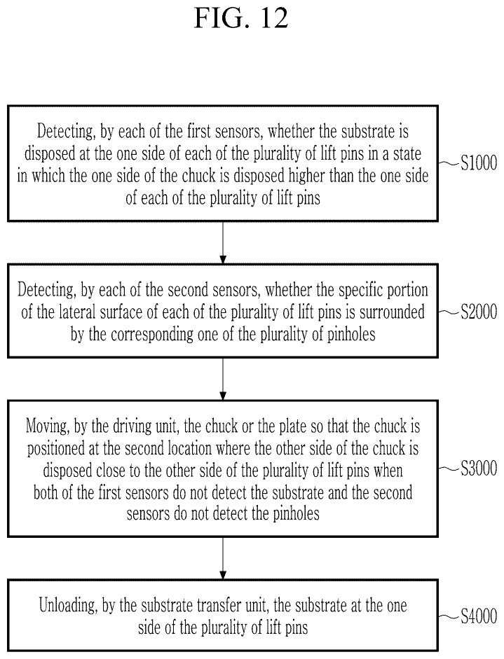

FIG. 12 is a diagram describing a substrate unloading method according to an embodiment.

As illustrated in FIG. 12, the substrate unloading method according to the present disclosure is a method for unloading the substrate 1 by using the substrate lifting device 10 described in FIGS. 4 to 6.

Here, the substrate lifting device 10 may include a plurality of lift pins 100, a chuck 200 including a plurality of pinholes 210 penetrated by respective lift pins 100, a plate 300 fixing the other side of each lift pin 100, a driving unit 400 moving the chuck 200 or the plate 300, and a plurality of sensor 500 disposed close to the other side of each lift pin 100, and the plurality of sensors 500 may include a first sensor 510 and a second sensor 520.

The substrate unloading method may include a step S1000 in which each first sensor 510 detects whether the substrate 1 is disposed at one side of each lift pin 100 in a state in which one side of the chuck 200 is placed at a first location disposed higher than one side of the plurality of lift pins 100, a step S2000 in which each second sensor 520 detects whether a specific portion of the lateral surface of each lift pin 100 is surrounded by the pinhole 210, a step S3000 in which when the detections are made in both of the plurality of first sensors 510 and second sensors 520, the driving unit 400 moves the chuck 200 or the plate 300 so that the other side of the chuck 200 is positioned at a second location disposed close to the other side of the plurality of lift pins 100, and a step S4000 in which the substrate transfer unit 900 unloads the substrate 1 from one side of the plurality of lift pins 100.

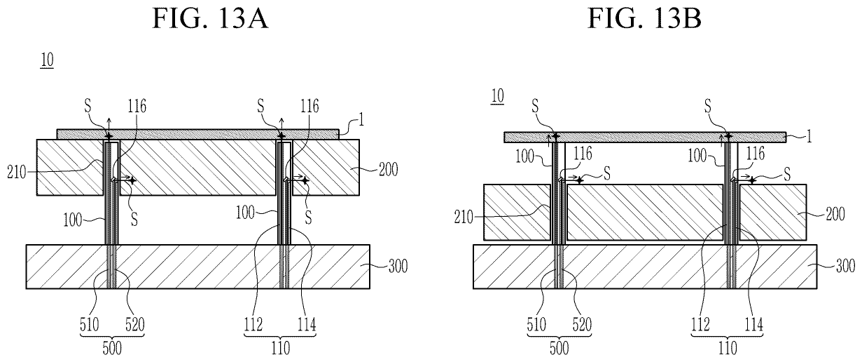

FIGS. 13A-13B are diagrams illustrated to describe a process before substrate unloading in the substrate unloading method according to FIG. 12.

FIG. 13A means the state in which the substrate 1 is loaded as in FIG. 11A, and when the substrate 1 is normally loaded, a result of detecting the substrate 1 by both the first sensor 510 and the second sensor 520 is obtained.

After it is confirmed that the substrate 1 is normally loaded, a step for unloading the substrate 1 may be started as in FIG. 13B.

FIG. 13B (the same as FIG. 11B) illustrates a state before unloading of the substrate 1 by the substrate transfer unit 900 starts after the chuck 200 is positioned at the second location.

The substrate unloading method according to the present disclosure may further include a step in which each first sensor 510 detects whether the substrate 1 is disposed at one side of each lift pin 100, and a step in which each second sensor 520 detects whether a specific portion on the lateral surface of each lift pin 100 is surrounded by the pinhole 210.

When the plurality of first sensors 510 detect the substrate 1 and the plurality of second sensors 520 do not detect the pinhole 210, the substrate transfer unit 900 may unload the substrate 1.

However, when at least one first sensor 510 of the plurality of first sensors 510 detects the first substrate 1, or at least one second sensor 520 of the plurality of second sensors 520 detects the pinhole 210, the control unit 800 may control the substrate lifting device 10 so as to stop the substrate unloading process.

However, the reason is that the case where at least one first sensor 510 does not detect the substrate 1 means a case where the substrate 1 is not normally disposed, and the case where either of the first sensors 510 do not detect the substrate 1 means a case where the substrate 1 is not disposed at one side of the lift pin 100.

Further, the reason is that the case where at least one second sensor 520 detects the pinhole 210 means a case where a problem in that the lift pin 100 does not appropriately protrude from the pinhole 210, or the lift pin 100 is bent occurs.

As described above, in the substrate lifting device 10, and the substrate loading and unloading method using the same according to the present disclosure, the sensor 500 disposed in the lift pin 100 transmits and receives the signal S through the hollow line 110 formed inside the lift pin 100 to detect whether the substrate 1 is disposed at one side of the lift pin 100, thereby preventing a problem in that the substrate 1 is redundantly loaded in the loading process.

Further, the sensor 500 detects whether the plurality of lift pins 100 protrude from the chuck 200 at the same height to determine the abnormal operation of the lift pins 100 in advance, thereby minimizing a damage risk of the substrate 1.

Although an example embodiment of the present disclosure is described hereinabove, the present disclosure is not limited thereto, and various modifications can be made within the scope of the claims, and the detailed description of the present disclosure and the accompanying drawings, and belongs to the scope of the present disclosure, of course.

What is claimed is:

1. A substrate lifting device comprising:
a lift pin having one side supporting a substrate, and including a hollow line therein;
a chuck including a pinhole penetrated by the lift pin, and having one side on which the substrate is seated;
a plate fixing the other side of the lift pin;
a driving unit configured to move the chuck or the plate so that the lift pin moves along the pinhole; and
sensors connected to the hollow line, and configured to transmit and receive signals through the hollow line.

2. The substrate lifting device of claim 1, wherein the hollow line includes:
a first hollow line connecting a first opening provided at the one side of the lift pin and a second opening provided at the other side of the lift pin; and
a second hollow line connecting a third opening provided at the one side of the lift pin and a fourth opening provided at a lateral surface of the lift pin.

3. The substrate lifting device of claim 2, wherein a reflector configured to reflect the signals is disposed inside the second hollow line.

4. The substrate lifting device of claim 2, wherein the driving unit is configured to move the chuck or the plate so that the chuck is positioned between a first location where the one side of the chuck is disposed higher than the one side of the lift pin, and a second location where the other side of the chuck is disposed close to the other side of the lift pin.

5. The substrate lifting device of claim 4, wherein the fourth opening is surrounded by the pinhole in a state in which the chuck is disposed at the first location, and disposed in the lift pin to deviate from the pinhole in a state in which the chuck is disposed at the second location.

6. The substrate lifting device of claim 2, wherein the sensors include:
a first sensor configured to detect a signal passing through the first hollow line to detect whether the substrate is disposed at the one side of the lift pin; and
a second sensor configured to detect a signal passing through the second hollow line to detect whether the fourth opening is disposed inside the pinhole.

7. The substrate lifting device of claim 6, wherein the first sensor includes:
a first light emitting unit configured to transmit the signal to the second opening from the first opening by passing through the first hollow line; and
a first light receiving unit configured to receive the signal reflected and returned through the second opening.

8. The substrate lifting device of claim 6, wherein the second sensor includes:
a second light emitting unit configured to transmit the signal to the fourth opening from the third opening by passing through the second hollow line; and
a second light receiving unit configured to receive the signal reflected and returned through the fourth opening.

9. The substrate lifting device of claim 2,
wherein the signals transmitted and received by the sensors are optical signals, and
wherein each of the sensors includes:
a light emitting unit configured to convert a transmitted electrical signal into the optical signal, and transmit the optical signal toward the second opening and the fourth opening; and
a light receiving unit configured to receive the optical signal reflected and returned on the second opening and the fourth opening, and convert the received optical signal to an electrical signal.

10. The substrate lifting device of claim 1, further comprising:
a determination unit configured to analyze the signals to determine whether the substrate is disposed at the one side of the lift pin, and determine whether the lift pin performs an abnormal operation in the process of loading and unloading the substrate.

11. A substrate lifting device comprising:
a lift pin having one side supporting a substrate, and including a hollow line therein;
a chuck including a pinhole penetrated by the lift pin, and having one side on which the substrate is seated;
a plate fixing the other side of the lift pin;
a driving unit configured to move the chuck or the plate so that the lift pin moves along the pinhole;
sensors connected to the hollow line, and configured to transmit and receive signals through the hollow line;
a determination unit configured to analyze the signals to determine whether the substrate is disposed at the one side of the lift pin, and determine whether the lift pin performs an abnormal operation in the process of loading and unloading the substrate; and
a control unit configured to control the driving unit to stop or terminate the process of loading and unloading the substrate according to the determination of the determination unit.

12. A method for loading and unloading a substrate by using a substrate lifting device, the substrate lifting device including a plurality of lift pins, a chuck including a plurality of pinholes penetrated by the plurality of lift pins, a plate fixing one side of each of the plurality of lift pins, a driving unit moving the chuck or the plate, and a plurality of sensors disposed close to the one side of each of the plurality of lift pins, the plurality of sensors including first sensors and second sensors, the method comprising:
detecting, by each of the first sensors, whether the substrate is disposed at the one side of each of the plurality of lift pins in a state in which one side of the chuck is disposed at a first location higher than the one side of the plurality of lift pins;
detecting, by each of the second sensors, whether a specific portion of a lateral surface of each of the plurality of lift pins is surrounded by a corresponding one of the plurality of pinholes;
moving, by the driving unit, the chuck or the plate so that the chuck is positioned at a second location where the other side of the chuck is disposed close to the other side of the plurality of lift pins when the first sensors do not detect the substrate and the second sensors detect the plurality of pinholes;
disposing, by a substrate transfer unit, the substrate at the one side of the plurality of lift pins; and
seating, by the driving unit, the substrate on the one side of the chuck, and loading the substrate by moving the chuck or the plate so that the chuck is positioned at the first location.

13. The method for loading and unloading the substrate of claim 12, further comprising:
determining, by a determination unit, whether an abnormal operation occurs in a substrate loading process according to detected results and undetected results in the plurality of sensors; and
controlling, by a control unit, the substrate lifting device so as to stop the substrate loading process when the determination unit determines that the abnormal operation occurs.

14. The method for loading and unloading the substrate of claim 13, further comprising:
in a state in which the chuck is disposed at the second location before the substrate transfer unit disposes the substrate at the one side of the plurality of lift pins,
stopping, by the control unit, the substrate loading process when at least one first sensor among the first sensors detects the substrate; and
stopping, by the control unit, the substrate loading process when at least one second sensor among the second sensors detects the corresponding one of the plurality of pinholes.

15. The method for loading and unloading the substrate of claim 13, further comprising:
before the chuck is disposed at the first location and before the substrate transfer unit disposes the substrate at the one side of the plurality of lift pins,
detecting, by each of the first sensors, whether the substrate is disposed at the one side of each of the plurality of lift pins; and
detecting, by each of the second sensors, whether the specific portion of the lateral surface of each of the plurality of lift pins is surrounded by the corresponding one of the plurality of pinholes,
wherein the first sensors detect the substrate and the second sensors do not detect the plurality of pinholes, the driving unit moves the chuck or the plate so that the chuck is positioned at the first location.

16. The method for loading and unloading the substrate of claim 15, wherein the control unit stops the substrate loading process when at least one second sensor among the second sensors detects the corresponding one of the plurality of pinholes.

17. The method for loading and unloading the substrate of claim 12, further comprising:
in a state in which the substrate is seated on the one side of the chuck after the driving unit moves the chuck or the plate so that the chuck is positioned at the first location,
detecting, by each of the first sensors, whether the substrate is disposed at the one side of each of the plurality of lift pins; and
detecting, by each of the second sensors, whether the lateral surface of each of the plurality of lift pins is surrounded by the corresponding one of the plurality of pinholes,
wherein when both detections are made, a control unit terminates a substrate loading process.

18. The method for loading and unloading the substrate of claim 12, further comprising:
detecting, by each of the first sensors, whether the substrate is disposed at the one side of each of the plurality of lift pins in a state in which the one side of the chuck is disposed higher than the one side of each of the plurality of lift pins;
detecting, by each of the second sensors, whether the specific portion of the lateral surface of each of the plurality of lift pins is surrounded by the corresponding one of the plurality of pinholes;
moving, by the driving unit, the chuck or the plate so that the chuck is positioned at the second location where the other side of the chuck is disposed close to the other side of the plurality of lift pins when both of the first sensors do not detect the substrate and the second sensors do not detect the pinholes; and
unloading, by the substrate transfer unit, the substrate at the one side of the plurality of lift pins.

19. The method for loading and unloading the substrate of claim 18, further comprising:
before the substrate is unloaded and after the chuck is positioned at the second location;
detecting, by each of the first sensors, whether the substrate is disposed at the one side of each of the plurality of lift pins; and
detecting, by each of the second sensors, whether the specific portion of the lateral surface of each of the plurality of lift pins is surrounded by the corresponding one of the pinholes,
wherein when the first sensors detect the substrate and the second sensors do not detect the pinholes, the substrate transfer unit unloads the substrate.

20. The method for loading and unloading the substrate of claim 18, further comprising:
before the substrate is unloaded and after the chuck is positioned at the second location, when at least one first sensor among the first sensors does not detect the substrate or at least one second sensor among the second sensors detects the pinhole,
controlling, by a control unit, the substrate lifting device so as to stop a substrate unloading process.
